(19) United States
(12) Patent Application Publication
(10) Pub. No.: US 2014/0353012 A1
(43) Pub. Date: Dec. 4, 2014

(54) TRANSPARENT CONDUCTIVE FILM

(71) Applicants: NANCHANG O-FILM TECH CO., LTD., NANCHANG CITY (CN); SHENZHEN O-FILM TECH CO., LTD., SHENZHEN CITY (CN); SUZHOU O-FILM TECH CO., LTD., SUZHOU CITY (CN)

(72) Inventors: Yunhua Zhao, Shenzhen City (CN); Yulong Gao, Shenzhen City (CN); Yunliang Yang, Shenzhen City (CN); Guanglong Xie, Shenzhen City (CN)

(73) Assignees: NANCHANG O-FILM TECH CO., LTD., NANCHANG CITY (CN); SHENZHEN O-FILM TECH CO., LTD., SHENZHEN CITY (CN); SUZHOU O-FILM TECH CO., LTD., SUZHOU CITY (US)

(21) Appl. No.: 13/975,271

(22) Filed: Aug. 23, 2013

Related U.S. Application Data
(63) Continuation of application No. PCT/CN2013/079187, filed on Jul. 11, 2013.

(30) Foreign Application Priority Data
May 30, 2013 (CN) 201310209717.2

(51) Int. Cl. H05K 1/02

(52) U.S. Cl. CPC H05K 1/0298
USPC 174/254

(57) ABSTRACT

A transparent conductive film includes: a transparent substrate, a conduction line, a first conductive layer, a first matrix layer, and a second conductive layer. The transparent substrate includes a body and a flexible board, and the body includes a sensing area and a border area; the first conductive layer is disposed on a side of the sensing area; the first matrix layer is disposed on the surface of the first conductive layer, and the second conductive layer is embedded in the first matrix layer; a first electrode trace disposed on a side of the border area, via which the first conductive layer and the conduction line are electrically connected; and a second electrode trace disposed on a side of the first matrix layer, via which the second conductive layer and the conduction line are electrically connected. The production efficiency of the above transparent conductive film is improved.

### CROSS REFERENCE TO RELATED APPLICATIONS

This application is a continuation of International Patent Application NO. PCT/CN2013/079187, filed on Jul. 11, 2013, which claims priority to Chinese Patent Application No. 201310209717.2, filed on May 30, 2013, both of which are hereby incorporated by reference in their entireties.

### TECHNICAL FIELD

The present invention relates to the field of touch screen and, in particular, to a transparent conductive film.

### BACKGROUND

Transparent conductive film is a thin film which has good conductivity and high optical transparency within a visible wavelength band. Currently, transparent conductive films have been widely used in the fields of flat panel display, photovoltaic devices, touch panel, electromagnetic shielding, and so on. Transparent conductive films have an extremely broad market potential.

A flexible circuit board is a highly reliable printed circuit board with excellent flexibility, which is made by using polyimide or polyester film as a substrate. The flexible circuit board, abbreviated as soft board or FPC (Flexible Printed Circuit), is characterized by high wiring density, light weight, and thin thickness. The transparent conductive film is connected to an external circuit through the FPC, so that a position signal sensed by the transparent conductive film can be transferred to a processor and identified, so as to determine the touch location.

Conventionally, when connecting a transparent conductive film to an external circuit through an FPC, firstly, the FPC is applied to a lead area of the transparent conductive film, and then the FPC is connected to a printed circuit board (PCB), which results in low production efficiency.

### SUMMARY

Based on this, it is necessary to provide a transparent conductive film which can be produced with high efficiency.

A transparent conductive film includes:

a transparent substrate, where the transparent substrate includes a body and a flexible board which is formed by extending from one end of the body, a width of the flexible board is less than a width of the body, the body comprises a sensing area and a border area which is located at an edge of the sensing area;

a conduction line, disposed on a side of the flexible transparent substrate;

a grid-shaped first conductive layer, disposed on a side of the sensing area, the first conductive layer includes first conductive wires intercrossing each other;

a first matrix layer, disposed on a surface of the first conductive layer away from the sensing area, and on a surface of the first matrix layer away from the first conductive layer, a grid-shaped second conductive layer is disposed, where the second conductive layer comprises second conductive wires intercrossing each other;

a first electrode trace, disposed on a side of the border area, where the first conductive layer and the conduction line are electrically connected via the first electrode trace; and

a second electrode trace, disposed on a side of the first matrix layer corresponding to the border area, where the second conductive layer and the conduction line are electrically connected via the second electrode trace.

In an embodiment of the present invention, at a surface of the first matrix layer away from the first conductive layer, a first groove is disposed, and the second conductive layer is accommodated in the first groove; at a surface of the sensing area, a second groove is disposed, and the first conductive layer is accommodated in the second groove.

In an embodiment of the present invention, the first electrode trace is embedded in a surface of the border area, or the first electrode trace is directly disposed on the surface of the border area;

the second electrode trace is embedded in a surface of the first matrix layer corresponding to the border area, or the second electrode trace is directly disposed on the surface of the first matrix layer corresponding to the border area.

In an embodiment of the present invention, the transparent conductive film further includes a second matrix layer, where the second matrix layer is disposed between the transparent substrate and the first matrix layer, and at a side of the second matrix layer away from the transparent substrate, a second groove is disposed, and the first conductive layer is accommodated in the second groove.

In an embodiment of the present invention, a bottom of the first groove is of a non-planar structure, a bottom of the second groove is of a non-planar structure.

In an embodiment of the present invention, a width of the first groove is 0.2 μm˜5 μm, a height of the first groove is 2 μm˜6 μm, and a height to width ratio is more than 1;

a width of the second groove is 0.2 μm˜5 μm, a height of the second groove is 2 μm˜6 μm, and a height to width ratio is more than 1.

In an embodiment of the present invention, the first electrode trace is embedded in a surface of the second matrix layer, or the first electrode trace is directly disposed on the surface of the second matrix layer.

In an embodiment of the present invention, a material of the transparent substrate is a thermoplastic material, the thermoplastic material is polycarbonate or polymethylmethacrylate;

a material of the first matrix layer is ultraviolet curable adhesive, embossed plastic or polycarbonate;

a material of the second matrix layer is ultraviolet curable adhesive, embossed plastic or polycarbonate.

In an embodiment of the present invention, the first electrode trace is grid-shaped or strip-shaped, the grid-shaped first electrode trace includes first conductive leads intercrossing each other, the strip-shaped first electrode trace has a minimal width of 10 μm˜200 μm, and a height of 5 μm˜20 μm;

the second electrode trace is grid-shaped or strip-shaped, the grid-shaped second electrode trace includes second conductive leads intercrossing each other, the strip-shaped second electrode trace has a minimal width of 10 μm˜200 μm, and a height of 5 μm˜20 μm.

In an embodiment of the present invention, the conduction line is grid-shaped or strip-shaped, the grid-shaped conduction line is formed by intercrossing conduction wires.

In an embodiment of the present invention, a material of the first conductive layer is a conductive metal, the conductive metal is silver or copper;

a material of the second conductive layer is a conductive metal, the conductive metal is silver or copper.

In an embodiment of the present invention, the transparent conductive film further includes a transparent protective layer, where the transparent protective layer covers at least a part of the transparent substrate, the first conductive layer, the second conductive layer, the first electrode trace, the second electrode trace and the conduction line.

In an embodiment of the present invention, a visible light transmittance of the transparent conductive film is not less than 86%.

According to embodiments of the present invention, the transparent substrate of the transparent conductive film includes a body and a flexible board; and the first conductive layer, the second conductive layer and the conduction line are disposed on the same transparent substrate so as to form a conductive film and a flexible circuit board. Therefore, comparing with the conventional method that needs to adhere a conductive film and a flexible circuit board by an adhering process, the production efficiency of the transparent conductive film according to embodiments of the present invention can be improved since an adhering process is not needed.

### BRIEF DESCRIPTION OF DRAWINGS

FIG. 1 is a schematic diagram of a cross-sectional structure of a transparent conductive film along a first conductive layer according to an embodiment of the present invention;

FIG. 2 is a schematic diagram of a cross-sectional structure of a transparent conductive film along a second conductive layer according to an embodiment of the present invention;

FIG. 3 is a schematic diagram of a cross-sectional structure of a transparent conductive film according to an embodiment of the present invention;

FIG. 4 is a schematic diagram of a cross-sectional structure of a transparent conductive film according to another embodiment of the present invention;

FIG. 5 is a schematic structural diagram of a groove bottom according to an embodiment of the present invention;

FIG. 6 is a schematic structural diagram of conductive grids according to an embodiment of the present invention;

FIG. 7 is a schematic structural diagram of conductive grids according to another embodiment of the present invention;

FIG. 8 is a schematic diagram of a cross-sectional structure of a transparent conductive film according to another embodiment of the present invention;

FIG. 9 is a schematic diagram of a cross-sectional structure of a transparent conductive film according to another embodiment of the present invention; and

FIG. 10 is a schematic diagram of a partial cross-sectional structure of the transparent conductive film shown in FIG. 8.

### DESCRIPTION OF EMBODIMENTS

To make the objectives, technical solutions, and advantages of embodiments of the present invention clearer, the following clearly and comprehensively describes the technical solutions in embodiments of the present invention with reference to the accompanying drawings. In the following, details of embodiments are described for more comprehensive understanding of the present application. However, the present invention can be implemented in many ways other than those embodiments described therein. Persons skilled in the art can make similar improvements without departing from the principle of the present invention. Therefore, the present invention is not limited to the following disclosed embodiments

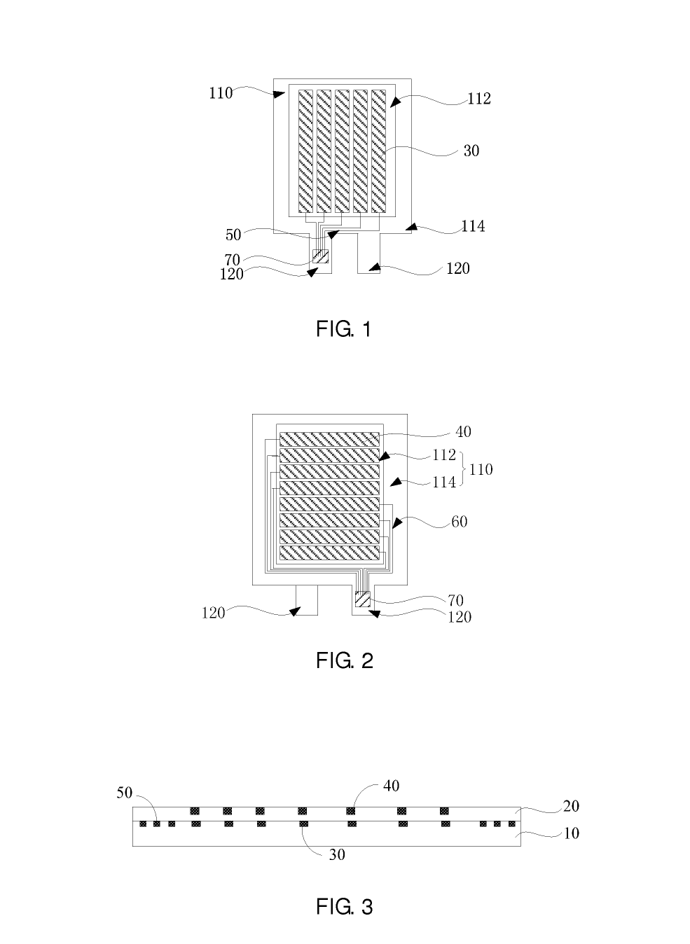

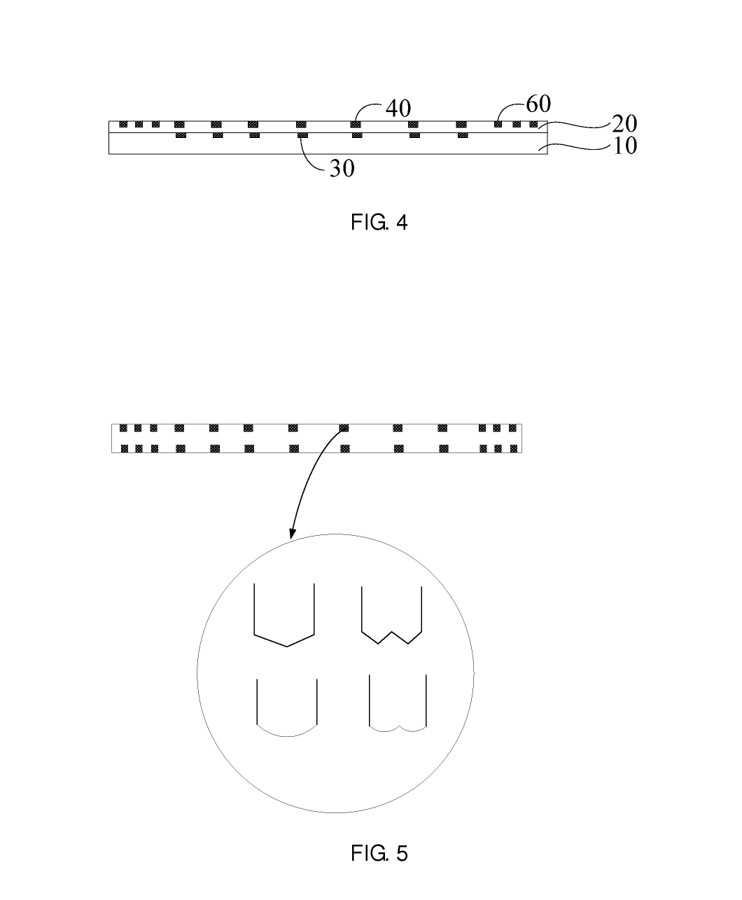

With reference to FIG. 1 to FIG. 4, a transparent conductive film according to an embodiment of the present invention includes a transparent substrate 10, a first matrix layer 20, a first conductive layer 30, a second conductive layer 40, a first electrode trace 50, a second electrode trace 60 and a conduction line 70.

The material of the transparent substrate 10 may be polyethylene terephthalate (PET) or thermoplastic material. The thermoplastic material may be polycarbonate (PC) or polymethylmethacrylate (PMMA).

The transparent substrate 10 includes a body 110 and a flexible board 120 which is formed by extending from one end of the body 110. The width of the flexible board 120 is less than the width of the body 110. The body 110 includes a sensing area 112 and a border area 114 which is disposed at the edge of the sensing area.

The material of the first matrix layer 20 may be ultraviolet curable adhesive (UV adhesive), embossed plastic or polycarbonate.

The first matrix layer 20 is disposed on the surface of the first conductive layer 30 away from the sensing area. At the surface of the first matrix layer 20, which is away from the first conductive layer 30, a first groove is disposed. At the surface of the first matrix layer 20 corresponding to the border area 114, a first electrode groove is disposed. The first electrode groove and the first groove are disposed on the same side.

A second groove is disposed on a surface of the sensing area 112. A second electrode groove is disposed on a surface of the border area 114. The second electrode groove and the second groove are disposed on the same side.

There is at least one flexible board 120. When one flexible board 120 is provided, a conduction groove is disposed on the flexible board 120. The conduction groove and the second groove are disposed on the same side. In this embodiment, two flexible boards 120 are provided. A conduction groove is disposed on the two flexible boards 120, respectively. Both of the two conduction grooves and the second groove are disposed on the same side.

For convenience of description, the first groove, the second groove, the first electrode groove, the second electrode groove and the conduction groove are all called groove unless indicated otherwise. With reference to FIG. 5, the bottom of the groove is of a non-planar structure. The bottom of the groove may be “V”-shaped, “W”-shaped, curved or wavy. The amplitude of the “V”-shaped, “W”-shaped, curved or wavy bottom of the groove is between 500 nm to 1 μm. As the bottom of the groove is set to be “V”-shaped, “W”-shaped, curved or wavy, the shrinkage of the conductive material can be reduced in the drying and curing process after the conductive material is filled into the groove. Filing the conductive material into the groove and curing the conductive material to form the first conductive wires, the second conductive wires, the first conductive leads, the second conductive leads and conduction wires, can effectively protect the performance of the conductive material and prevent the breakage of the conductive material caused by shrinkage of the conductive material during the baking process. The width of the groove may be 0.2 μm˜5 μm, the height of the groove may be 2 μm˜6 μm, and the height to width ratio is more than 1.

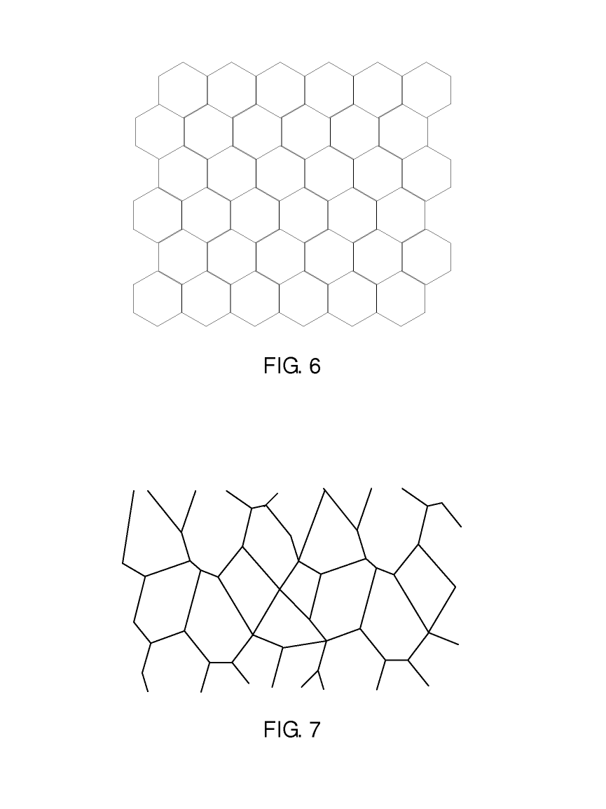

The first conductive layer 30 is accommodated in the second groove. The first conductive layer 30 is grid-shaped. With reference to FIG. 6 and FIG. 7, the grids of the first conductive layer 30 may be regular grids (FIG. 6) with repeated pattern or random grids (FIG. 7). The first conductive layer 30 comprises the first conductive wires intercrossing each other. The first conductive layer is formed by curing the conductive material filled into the second groove. The material of the first conductive layer may be conductive metal, and the conductive metal may be silver or copper.

The second conductive layer 40 is accommodated in the first groove. The second conductive layer 40 is grid-shaped. With reference to FIG. 6 and FIG. 7, the grids of the second conductive layer 40 may be regular grids with repeated pattern (FIG. 6) or random grids (FIG. 7). The second conductive layer 40 comprises the second conductive wires intercrossing each other. The second conductive layer is formed by curing the conductive material filled into the second groove. The material of the second conductive layer may be conductive metal, and the conductive metal may be silver or copper.

The first electrode traces 50 and the second electrode traces 60 are accommodated in the second electrode groove and the first electrode groove, respectively. The first electrode traces 50 and the first conductive layer 30 are on the same side. The first conductive layer 30 and the conduction line 70 are electrically connected via the first electrode traces 50. The second electrode traces 60 and the second conductive layer 40 are on the same side. The second conductive layer 40 and the second electrode traces 60 are electrically connected. The second electrode traces 60 may pass through the first matrix layer 20 to the surface of the first conductive layer 30 via a through hole of the first matrix layer 20, and then is electrically connected to the conduction line 70. The second electrode traces 60 and the first conductive layer are insulated from each other.

The first conductive layer 30 and the conduction line 70 are electrically connected via the first electrode traces 50, and the second conductive layer 40 and the conduction line 70 are electrically connected via the second electrode traces 60, so as to transfer touch signals sensed by the sensing area to the conduction line 70.

The first electrode traces 50 may be grid-shaped or strip-shaped. The second electrode traces 60 may also be grid-shaped or strip-shaped.

The grid-shaped first electrode traces 50 includes first conductive leads intercrossing each other. Referring to FIG. 6 and FIG. 7, the grids of the first electrode traces 50 may be regular grids (FIG. 6) or random grids (FIG. 7). The first electrode traces 50 is formed by curing the conductive material filled into the second electrode groove. The material of the first electrode traces 50 may be a conductive metal, and the conductive metal may be silver or copper.

For the strip-shaped first electrode traces 50, a minimal width may be 10 μm˜200 μm, and the height may be 5 μm˜20 μm.

The grid-shaped second electrode traces 60 include second conductive leads intercrossing each other. Referring to FIG. 6 and FIG. 7, the grids of the second electrode traces 60 may be regular grids (FIG. 6) or random grids (FIG. 7). The second electrode traces 60 are formed by curing the conductive material filled into the first electrode groove. The material of the second electrode trace 60 may be a conductive metal, and the conductive metal may be silver or copper.

For the strip-shaped second electrode traces 60, a minimal width may be 10 μm˜200 μm, and the height may be 5 μm˜20 μm.

In this embodiment, there are two conduction lines 70, accommodated in the two conduction grooves, respectively. The conduction line 70 may be grid-shaped or strip-shaped.

The grid-shaped conduction line 70 includes conduction wires intercrossing each other. Referring to FIG. 6 and FIG. 7, the grids of the conduction line 70 may be regular grids (FIG. 6) or random grids (FIG. 7). The conduction line 70 is formed by curing the conductive material filled into the conduction groove. The material of the conduction line 70 may be a conductive metal, and the conductive metal may be silver or copper.

Of course, in other embodiments of the present invention, the first electrode traces 50 and the second electrode traces 60 may also be disposed as follows:

(1) The first electrode traces 50 may be directly disposed on the surface of the border area, and the first electrode traces 50 and the first conductive layer 30 are on the same side. In this case, the first electrode traces 50 are formed by screen printing, lithography or inkjet printing. The second electrode traces 60 may also be disposed directly on the surface of the first matrix layer 20 corresponding to the border area, and the second electrode traces 60 and the second conductive layer 40 are on the same side. In this case, the second electrode traces 60 are formed by screen printing, lithography or inkjet printing.

(2) The first electrode traces 50 may be directly disposed on the surface of the border area, and the first electrode traces 50 and the first conductive layer 30 are on the same side. The second electrode traces 60 are accommodated in the first groove of the first electrode matrix layer, and the second electrode traces 60 and the second conductive layer 40 are on the same side. In this case, the first electrode traces 50 are formed by screen printing, lithography or inkjet printing. The second electrode traces 60 are formed by curing the conductive material filled into the first electrode groove.

(3) The first electrode traces 50 are accommodated in the second electrode groove of the border area, and the first electrode traces 50 and the first conductive layer 30 are in the same side. The second electrode traces 60 are directly disposed on the surface of the first matrix layer, and the second electrode traces 60 and the second conductive layer 40 are in the same side. In this case, the first electrode traces 50 are formed by curing the conductive material filled into the second electrode groove. The second electrode traces 60 are formed by screen printing, lithography or inkjet printing.

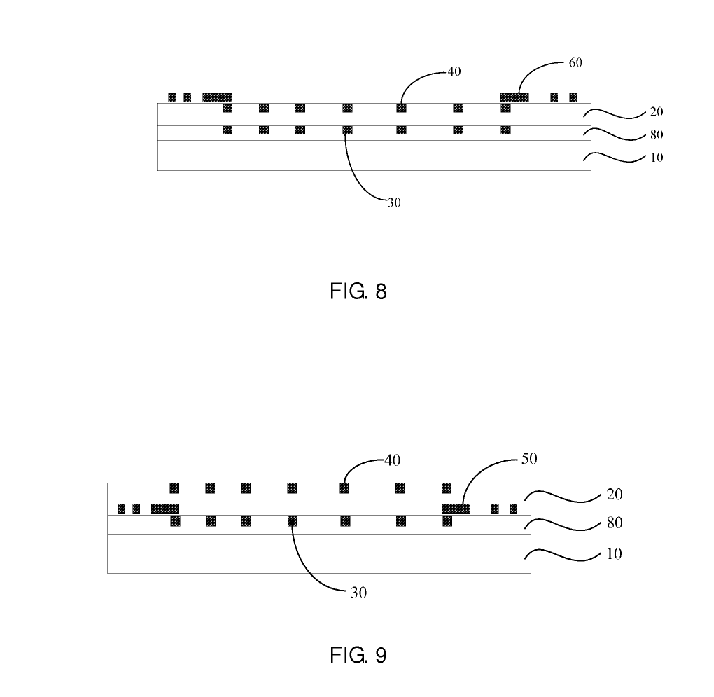

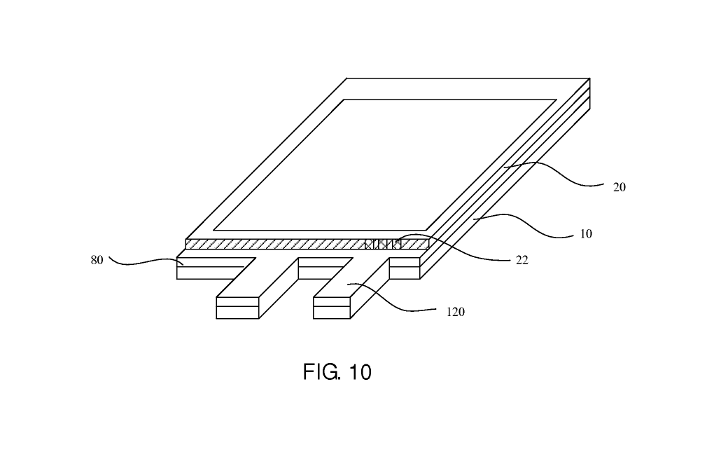

As shown in FIG. 8 and FIG. 9, the transparent conductive film further includes a second matrix layer 80. The second matrix layer 80 is disposed between the transparent substrate 10 and the first matrix layer 20. At the side of the second matrix layer, which is away from the transparent substrate and corresponds to the sensing area, a second groove is disposed, and the first conductive layer 30 is accommodated in the second groove. The first electrode traces 50 are disposed directly on the surface of the second matrix layer 80, corresponding to the border area. The second electrode traces 60 are disposed directly on the surface of a first the matrix layer 20, corresponding to the border area. With reference to FIG. 10, the second electrode traces 60 pass through hole 22 and arrives at the surface of the first conductive layer 30 and, then, is electrically connected to the conduction line 70.

The other structures of the transparent conductive film in the embodiments shown in FIG. 8 and FIG. 9 are similar with the relevant structures of the transparent conductive film in the embodiments shown in FIG. 3 and, thus, are not further discussed here.

The material of the second matrix layer 80 may be ultraviolet curable adhesive, embossed plastic or polycarbonate.

For convenience of description, the bottom of the second groove may be “V”-shaped, “W”-shaped, curved or wavy unless indicated otherwise. The amplitude of the “V”-shaped, “W”-shaped, curved or wavy bottom of the second groove is between 500 nm to 1 μm. As the bottom of the second groove is set to be “V”-shaped, “W”-shaped, curved or wavy, the shrinkage of the conductive material can be reduced in the drying and curing process after the conductive material is filled into the groove. Filling the conductive material into the second groove and curing the conductive material to form the first conductive wires can effectively protect the performance of the conductive material and prevent the breakage of the conductive material during the baking process. The width of the second groove may be 0.2 μm˜5 μm, the height of the groove may be 2 μm˜6 μm, and the height to width ratio is more than 1.

As will be appreciated that, in other embodiments, the first electrode traces 50 and the second electrode traces 60 may also be disposed as follows:

(1) The first electrode traces 50 may also be embedded in the surface of the second matrix layer 80 corresponding to the border area. The first electrode traces 50 and the first conductive layer 30 are on the same side. The second electrode traces 60 may be disposed directly on the surface of the first matrix layer 20 corresponding to the border area, and the second electrode traces 60 and the second conductive layer 40 are on the same side.

(2) The first electrode traces 50 may be directly disposed on the surface of the second matrix layer 80 corresponding to the border area, and the first electrode traces 50 and the first conductive layer 30 are on the same side. The second electrode traces 60 are embedded in the surface of the first matrix layer 20 corresponding to the border area, and the second electrode traces 60 and the second conductive layer 40 are on the same side.

(3). The first electrode traces 50 may also be embedded in the surface of the second matrix layer 80 corresponding to the border area. The first electrode traces 50 and the first conductive layer 30 are on the same side. The second electrode traces 60 may be directly disposed on the surface of the first matrix layer 20, and the second electrode traces 60 and the second conductive layer 40 are on the same side.

The transparent conductive film according to embodiments of the present invention may further include a transparent protective layer (not shown in the FIGs). The transparent protective layer covers at least a part of the transparent substrate 10, the first matix layer 20, the first conductive layer 30, the second conductive layer 40, the first electrode traces 50, the second electrode traces 60 and the conduction line 70. The material of the transparent protective layer may be UV adhesive, embossed plastic or polycarbonate.

The transparent protective layer of the transparent conductive film can effectively prevent the oxidation of the conductive material.

The visible light transmittance of the transparent conductive film described above is not less than 86%.

According to embodiments of the present invention, the transparent substrate of the transparent conductive film includes a body 110 and a flexible board 120; and the first conductive layer 30, the second conductive layer 40 and the conduction line 70 are disposed on the same transparent substrate so as to form a conductive film and a flexible circuit board. Therefore, comparing with the conventional method that needs to adhere a conductive film and a flexible circuit board by an adhering process, the production efficiency of the transparent conductive film according to embodiments of the present invention can be improved since an adhering process is not needed. The connection between a flexible connecting component and an external device can be realized via adhering or bonding, or via direct plug-in connecting by providing a male or female end at the end portion of the flexible connecting component. Meanwhile, since the adhering or bonding process is not needed, the production cost can be lowered, and the production yield can be improved.

It should be noted that the foregoing embodiments merely describe several implementing modes of the present invention with specific details, and should not be interpreted as limiting the present invention. Persons of ordinary skill in the art may make variants and modifications to the technical solutions described in the foregoing embodiments without departing from the conception of the present invention, all of these variants and modifications fall within the protection scope of the present invention. Accordingly, the scope of protection of the present invention should subject to the appended claims.

What is claimed is:

1. A transparent conductive film, comprising:
a transparent substrate, wherein the transparent substrate comprises a body and a flexible board which is formed by extending from one end of the body, a width of the flexible board is less than a width of the body, the body comprises a sensing area and a border area which is located at an edge of the sensing area;
a conduction line, disposed on a side of the flexible transparent substrate;
a grid-shaped first conductive layer, disposed on a side of the sensing area, the first conductive layer comprises first conductive wires intercrossing each other;
a first matrix layer, disposed on a surface of the first conductive layer away from the sensing area, and on a surface of the first matrix layer away from the first conductive layer, a grid-shaped second conductive layer is disposed, wherein the second conductive layer comprises second conductive wires intercrossing each other;
a first electrode trace, disposed on a side of the border area, wherein the first conductive layer and the conduction line are electrically connected via the first electrode trace; and
a second electrode trace, disposed on a side of the first matrix layer corresponding to the border area, wherein the second conductive layer and the conduction line are electrically connected via the second electrode trace.

2. The transparent conductive film according to claim 1, wherein:
at a surface of the first matrix layer away from the first conductive layer, a first groove is disposed, and the second conductive layer is accommodated in the first groove; at a surface of the sensing area, a second groove is disposed, and the first conductive layer is accommodated in the second groove.

3. The transparent conductive film according to claim 2, wherein:
the first electrode trace is embedded in a surface of the border area, or the first electrode trace is directly disposed on the surface of the border area;
the second electrode trace is embedded in a surface of the first matrix layer corresponding to the border area, or the second electrode trace is directly disposed on the surface of the first matrix layer corresponding to the border area.

4. The transparent conductive film according to claim 1, further comprising:
a second matrix layer, wherein the second matrix layer is disposed between the transparent substrate and the first matrix layer, and at a side of the second matrix layer away from the transparent substrate, a second groove is disposed, and the first conductive layer is accommodated in the second groove.

5. The transparent conductive film according to claim 2, wherein:
a bottom of the first groove is of a non-planar structure, a bottom of the second groove is of a non-planar structure.

6. The transparent conductive film according to claim 2, wherein:
a width of the first groove is 0.2 μm˜5 μm, a height of the first groove is 2 μm˜6 μm, and a height to width ratio is more than 1;
a width of the second groove is 0.2 μm˜5 μm, a height of the second groove is 2 μm˜6 μm, and a height to width ratio is more than 1.

7. The transparent conductive film according to claim 4, wherein:
the first electrode trace is embedded in a surface of the second matrix layer, or the first electrode trace is directly disposed on the surface of the second matrix layer.

8. The transparent conductive film according to claim 4, wherein:
a material of the transparent substrate is a thermoplastic material, the thermoplastic material is polycarbonate or polymethylmethacrylate;
a material of the first matrix layer is ultraviolet curable adhesive, embossed plastic or polycarbonate;
a material of the second matrix layer is ultraviolet curable adhesive, embossed plastic or polycarbonate.

9. The transparent conductive film according to claim 1, wherein:
the first electrode trace is grid-shaped or strip-shaped, the grid-shaped first electrode trace comprises first conductive leads intercrossing each other, the strip-shaped first electrode trace has a minimal width of 10 μm˜200 μm, and a height of 5 μm˜20 μm;
the second electrode trace is grid-shaped or strip-shaped, the grid-shaped second electrode trace comprises second conductive leads intercrossing each other, the strip-shaped second electrode trace has a minimal width of 10 μm˜200 μm, and a height of 5 μm˜20 μm.

10. The transparent conductive film according to claim 1, wherein:
the conduction line is grid-shaped or strip-shaped, the grid-shaped conduction line is formed by intercrossing conduction wires.

11. The transparent conductive film according to claim 1, wherein:
a material of the first conductive layer is a conductive metal, the conductive metal is silver or copper;
a material of the second conductive layer is a conductive metal, the conductive metal is silver or copper.

12. The transparent conductive film according to claim 1, further comprising:
a transparent protective layer, wherein the transparent protective layer covers at least a part of the transparent substrate, the first conductive layer, the second conductive layer, the first electrode trace, the second electrode trace and the conduction line.

13. The transparent conductive film according to claim 1, wherein:
a visible light transmittance of the transparent conductive film is not less than 86%.

14. The transparent conductive film according to claim 4, wherein:
a bottom of the first groove is of a non-planar structure, a bottom of the second groove is of a non-planar structure.

14. The transparent conductive film according to claim 4, wherein:
a width of the first groove is 0.2 μm˜5 μm, a height of the first groove is 2 μm˜6 μm, and a height to width ratio is more than 1;
a width of the second groove is 0.2 μm˜5 μm, a height of the second groove is 2 μm˜6 μm, and a height to width ratio is more than 1.
